(19) United States
(12) Patent Application Publication
(10) Pub. No.: US 2022/0295674 A1
(43) Pub. Date: Sep. 15, 2022

(54) AIR HEAT EXCHANGER AND METHOD FOR PRODUCTION THEREOF AND ELECTRONIC ASSEMBLY EQUIPPED THEREWITH

(71) Applicant: DAU GmbH & Co KG, Laakirchen (AT)

(72) Inventors: Samuel WALLNER, Ligist (AT); Rene HOESELE, Liebach (AT); Djenan CUSTIC, Graz (AT)

(73) Assignee: DAU GmbH & Co KG, Laakirchen (AT)

(21) Appl. No.: 17/632,447

(22) PCT Filed: Aug. 6, 2020
(86) PCT No.: PCT/AT2020/060289

§ 371 Date: Feb. 2, 2022

(30) Foreign Application Priority Data
Aug. 8, 2019 (AT) A50702/2019

(51) Int. Cl. H05K 7/20

(52) U.S. Cl. CPC H05K 7/20936; H05K 7/20909; H05K 7/20318; H05K 7/20309; H05K 7/20436

(57) ABSTRACT

The invention relates to an air heat exchanger 1 for cooling a power electronics component 2, comprising:
a carrier plate 3 having an accommodating region 4 for accommodating the power electronics component 2;
a heat exchanger plate 7 which is coupled to the carrier plate 3, wherein at least one hermetically sealed cavity 10 for accommodating a working medium 13 is formed and delimited by the carrier plate 3 and the heat exchanger plate 7, wherein the cavity 10 comprises an evaporator 11 and a condenser 12, wherein the evaporator 11 is arranged so as to be spaced apart from the condenser 12 in a heat transport direction 14;
cooling ribs 15 which are coupled to the heat exchanger plate 7.

The invention relates to an air heat exchanger for cooling a power electronics component.

A design of an air heat exchanger is known from EP0051315A2. Although it already was the object of EP0051315A2 to improve heat dissipation of the individual components, this is still insufficiently achieved in EP0051315A2 for components with a high heat output, such as power electronics components.

It was the object of the present invention to overcome the shortcomings of the prior art and to provide an air heat exchanger which has an improved heat dissipation also for electronic components with a high heat output.

The use of a liquid heat exchanger would be one possibility of how to improve heat dissipation. However, liquid heat exchangers have the disadvantage of having a high energy consumption for the circulation of the cooling medium. Moreover, liquid heat exchangers have a complex structure which entails a not inconsiderable susceptibility to errors. For this reason, the use of liquid heat exchangers is precluded in the present field of application.

The object of the invention is achieved by an air heat exchanger according to the claims.

The invention relates to an air heat exchanger for cooling a power electronics component, comprising:
a carrier plate having an accommodating region for accommodating the power electronics component;
a heat exchanger plate which is coupled to the carrier plate, wherein at least one hermetically sealed cavity for accommodating a working medium is formed and delimited by the carrier plate and the heat exchanger plate, wherein the cavity comprises an evaporator and a condenser, wherein the evaporator is arranged so as to be spaced apart from the condenser in a heat transport direction;
cooling ribs which are coupled to the heat exchanger plate.

Air flows around the cooling ribs of the air heat exchanger in operation of the air heat exchanger, whereby the amount of heat generated by the power electronics component may be dissipated to the surroundings as efficiently as possible.

The design of the air heat exchanger according to the invention entails the surprising advantage that, by the hermetically sealed cavity and the working medium accommodated therein and/or by the arrangement according to the invention of the hermetically sealed cavity, an efficiency enhancement of 20-30% as compared to an air heat exchanger formed without a cavity may be achieved. This surprisingly high efficiency factor enhancement may be achieved in particular in that the amount of heat of the power electronics component introduced into the carrier plate in the accommodating region may be uniformly conducted to the cooling ribs, which are coupled to the heat exchanger plate, wherein the entirety of the cooling ribs can dissipate the amount of heat to the ambient air in approximately equal measure.

Moreover, it may be useful for the carrier plate to have a carrier plate connecting surface and for the heat exchanger plate to have a heat exchanger plate connecting surface, wherein the carrier plate connecting surface and the heat exchanger plate connecting surface abut on one another. That the carrier plate connecting surface and the heat exchanger plate connecting surface abut on one another also comprises the state in which an intermediate layer, such as a layer of solder or an adhesive layer, is formed between the carrier plate connecting surface and the heat exchanger plate connecting surface.

Moreover, it may be provided that the carrier plate connecting surface is arranged on the opposite side of the accommodating region of the carrier plate.

Furthermore, it may be provided that the heat exchanger plate connecting surface is arranged on the side of the heat exchanger plate opposite with respect to the cooling ribs.

Moreover, it may be provided that the carrier plate connecting surface and the heat exchanger plate connecting surface are each formed as planar surfaces, wherein the cavity is formed by a recess in the heat exchanger plate connecting surface. This entails the surprising advantage that the air heat exchanger can have a structure that is as simple as possible and, moreover, has an efficiency that is as high as possible.

Alternatively or additionally to this, it may be provided that the recess for forming the cavity is arranged in the carrier plate.

Moreover, it may be provided that the carrier plate connecting surface and the heat exchanger plate connecting surface are coupled to one another by a materially bonded connection, in particular by a vacuum brazing connection. By such a materially bonded connection, a tight closure of the cavity may be achieved. Moreover, by the vacuum brazing connection, a particularly tight closure of the cavity and/or a simple establishment of the connection between the carrier plate and the heat exchanger plate may be achieved. In addition to this, when a vacuum brazing connection is established, the working medium may be easily introduced into the cavity.

A design, according to which it may be provided that webs are arranged in the recess at least in the region of the evaporator, said webs abutting on the carrier plate connecting surface, is also advantageous. This entails the advantage that by the webs, the heat conductivity between the carrier plate and the heat exchanger plate may be improved, whereby a further surprising increase in efficiency of the air heat exchanger may be achieved. Moreover, the webs may serve as a support element, whereby the stability of the air heat exchanger and/or the shape retention of the cavity may be improved.

In the alternative to this, it may be provided that webs are arranged in the recess at least in the region of the evaporator, said webs abutting on the heat exchanger plate connecting surface.

According to an advancement, it is possible that multiple ones of the webs are arranged in a row, wherein multiple rows of webs are arranged behind one another. This entails the advantage that the efficiency of the air heat exchanger may be further improved.

Furthermore, it may be provided that the individual webs of one row and/or of different rows have a dimensioning differing from one another and/or that the individual webs are arranged at different distances from one another. This entails the advantage that the distribution of the webs is adapted to the respective requirements of heat dissipation.

In particular, it may be provided that multiple rows of webs are arranged behind one another in the heat transport direction.

Furthermore, it may be provided that the individual webs in the heat transport direction have a longitudinal extension and transversely to the heat transport direction have a transverse extension, wherein the longitudinal extension is larger than the transverse extension. Moreover, it may be provided that the individual webs have a longitudinal extension of between 2 mm and 50 mm, in particular between 4 mm and 20 mm, preferably between 6 mm and 10 mm. Moreover, it may be provided that the individual webs have a transverse extension of between 1 mm and 20 mm, in particular between 2 mm and 10 mm, preferably between 3 mm and 4 mm.

Moreover, it may be provided that at least one spacer is formed in the region of the condenser. The spacer is designed such that the carrier plate abuts on the spacer. Furthermore, it may be provided that the spacer in the heat transport direction has a longitudinal extension and transversely to the heat transport direction has a transverse extension, wherein the longitudinal extension is larger than the transverse extension. Moreover, it may be provided that the spacer has a longitudinal extension of between 20 mm and 300 mm, in particular between 50 mm and 200 mm, preferably between 120 mm and 130 mm. Moreover, it may be provided that the spacer has a transverse extension of between 1 mm and 20 mm, in particular between 2 mm and 15 mm, preferably between 4 mm and 8 mm.

Moreover, it may be useful if at least two cavities are formed. This entails the surprising advantage that the efficiency of the air heat exchanger may be further improved as compared to an individual, larger dimensioned cavity. In this regard, the individual cavities may be arranged in the air heat exchanger independently and so as to not be connected to one another.

Furthermore, it may be provided that the at least two cavities are arranged next to one another, wherein the at least two cavities have opposite heat transport directions. This entails the surprising advantage of an improved heat distribution.

Moreover, it may be provided that cooling rib receptacles, in which the cooling ribs are received, are formed in the heat exchanger plate. Such an embodiment of the heat exchanger, in which the cooling ribs are not formed in one piece with the heat exchanger plate but are formed separately and are received in the heat exchanger plate, entails the advantage that the heat exchanger plate may be produced easily and cost-effectively.

In an alternative variant, it may be provided that cooling ribs are formed in one piece with the heat exchanger plate. This may for example be achieved by the heat exchanger plate being formed as a continuous casting profile.

Furthermore, it may be provided that the heat exchanger plate is formed as a deep-drawing part. In this case, the cooling ribs may also be formed in one piece with the heat exchanger plate.

In particular, it may be provided that the accommodating plate and/or the heat exchanger plate is formed of aluminum and/or of an aluminum alloy.

Furthermore, it may be provided that the cooling ribs received in the cooling rib receptacle for using a material with good thermal conductivity, such as a heat-conducting paste.

The cooling ribs may be produced from the same material as the heat exchanger plate.

Furthermore, it may be provided that the evaporator is arranged in the accommodating region, wherein the accommodating region is arranged off-center of the carrier plate as seen in top view. By the off-center arrangement of the accommodating region, a design of the air heat exchanger which is as space-saving and efficient as possible may be achieved. At the same time, by the formation of the cavity, a uniform heat spread onto the entire surface of the heat exchanger plate may be achieved.

According to a particular embodiment, it is possible that the cavity comprises the evaporator and multiple ones of the condensers, wherein, starting out from the evaporator towards the condensers, multiple heat transport directions are formed. By these measures, a uniform heat distribution and/or heat spread may be achieved at the heat exchanger plate. Thus, the cooling performance of the air heat exchanger may be surprisingly further increased.

In particular, it may be provided that the evaporator, as seen in top view, is arranged centrally on the carrier plate and that the condensers are arranged on the carrier plate around the evaporator. For example, the evaporator may be arranged centrally, and a first condenser may be arranged at a distance in the direction and a second condenser may be arranged at a distance in a second direction.

According to an advantageous advancement, it may be provided that the carrier plate has a carrier plate thickness of between 1 mm and 10 mm, in particular between 1.5 mm and 5 mm, preferably between 2 mm and 3 mm.

In particular, it may be advantageous if the heat exchanger plate has a heat exchanger plate thickness of between 5 mm and 50 mm, in particular between 15 mm and 35 mm, preferably between 24 mm and 27 mm.

Furthermore, it may be provided that a carrier plate thickness amounts to between 5% and 40%, in particular between 10% and 20%, preferably between 15% and 17%, of a heat exchanger plate thickness. Particularly such a ratio between the carrier plate thickness and the heat exchanger plate thickness entails a surprising increase in efficiency of the air heat exchanger.

Furthermore, it may be provided that the heat exchanger plate and/or the carrier plate are produced by a machining process, in particular by milling. Especially the recess in the heat exchanger plate may be easily produced by milling, wherein here, diverse shapes may be realized.

In an alternative embodiment variant, it may be provided that the heat exchanger plate and/or the carrier plate are produced by a casting process, in particular by a die casting process. In a preferred embodiment variant, the heat exchanger plate and/or the carrier plate may be produced by an aluminum die casting process.

Moreover, it may be provided that the cooling ribs are arranged such that the longitudinal extension of the cooling ribs as seen in top view onto the heat exchanger plate connecting surface are formed transversely to the heat transport direction. Particularly in such an arrangement of the cooling ribs, an above-average increase in efficiency of the air heat exchanger may be achieved.

In an alternative variant, it may also be provided that the cooling ribs are arranged such that the longitudinal extension of the cooling ribs as seen in top view onto the heat exchanger plate connecting surface are formed longitudinally to the heat transport direction.

Moreover, it may be provided that the cooling ribs are arranged both under the evaporator and under the condenser. In particular, it may be provided that, as seen in the heat transport direction, the cooling ribs are formed uniformly across a region starting from the outermost end and/or across the entire base surface of the evaporator up to the outermost end and/or across the entire base surface of the condenser.

Furthermore, it may be provided that an opening is formed in the carrier plate, said opening being designed to be closed by means of a footing of the power electronics component. In such an exemplary embodiment, the footing of the power electronics component may delimit the cavity, whereby a particularly efficient heat dissipation from the power electronics component may be achieved. In such an exemplary embodiment, it may also be provided that the carrier plate and the heat exchanger plate are formed in one piece and are designed, for example, in the form of a casting part.

In an advancement, it may be provided that the cavity comprises a vapor flow channel and comprises a liquid return channel at a constructional distance therefrom. This entails the advantage that the condensed working medium can be returned from the condenser to the evaporator in the liquid return channel and the evaporated working medium can pass from the evaporator to the condenser in the vapor flow channel Thus, the working medium may be guided into a cycle, whereby the cooling efficiency may be surprisingly increased, since no heat exchange between the condensed working medium and the evaporated working medium takes place.

Furthermore, it may be provided that a porous structure or a wick is arranged in the liquid return channel. This entails the advantage that the return of the working medium may be improved.

In addition to this, it may be provided that a depression, which has its deepest point in the region of the evaporator, is formed in a recess base of the recess. This entails the advantage that the working medium may be conveyed back into the evaporator in its liquid state by gravity.

In a further embodiment variant, it may be provided that multiple evaporators and/or multiple condensers are formed in a cavity.

Furthermore, it may be provided that a filling opening that is in flow connection with the cavity is formed in the carrier plate or in the heat exchanger plate. This entails the advantage that after connection of the carrier plate with the heat exchanger plate the working medium may be inserted into the cavity via the filling opening and the desired pressure in the cavity may be set via the filling opening.

In addition to this, it may be provided that the filling opening in the installed state of the air heat exchanger is pressed in such a way that it is tightly sealed. This entails the advantage that the filling opening may be easily compressed by means of a pressing stamp so that the filling opening can be closed.

In an alternative variant, it may be provided that the filling opening is closed by means of a plug. In this regard, the plug may have a sealing.

In yet another embodiment variant, it may be provided that the filling opening is closed by means of a screw, such as a grub screw.

According to the invention, an electronic assembly is formed. The electronic assembly comprises:
an air heat exchanger;
a power electronics component, in particular an insulated-gate bipolar transistor, arranged on the air heat exchanger.

The air heat exchanger is formed according to one of the aforementioned designs.

The electronic assembly according to the invention entails the advantage that due to the use of the improved air heat exchanger, a power electronics component with an increased operational performance and thus an increased heat dissipation amount may be used in the same installation space. Particularly insulated-gate bipolar transistors require a high heat energy discharge amount.

According to an advancement, it is possible that the power electronics component is arranged in the region of the evaporator of the air heat exchanger and that a further electronic component is arranged in the region of the condenser, wherein the further electronic component has a lower heat dissipation performance than a heat dissipation performance of the power electronics component. This entails the advantage that multiple components can be mounted on the air heat exchanger, wherein efficient cooling of all electronic components arranged on the air heat exchanger may be achieved by means of the air heat exchanger.

The structure according to the invention of the cavity in the air heat exchanger acts like a heat pipe. In a first embodiment variant, the air heat exchanger, in particular the cavity, may have the function of a heat pipe. In a second embodiment variant, the air heat exchanger, in particular the cavity, may have the function of a two phase thermosiphon. Both embodiment variants have in common that the working medium is converted into the gaseous state in the evaporator and the working medium arrives at the condenser in the gaseous state. In the condenser, the working medium is converted back into the liquid state and arrives at the heat pipe by the wick effect of a porous structure and, when the two phase thermosiphon is carried out, arrives back at the evaporator by gravity.

According to the invention, a method for producing an air heat exchanger, in particular an air heat exchanger according to one of the preceding claims, is provided. The method comprises the following method steps:
connecting a carrier plate to a heat exchanger plate;
filling a cavity with a working medium via the filling opening;
setting the desired pressure in the cavity;
hermetically sealing the cavity by pressing the filling opening.

For example, alcohols, acetone or any other refrigerant may be used as the working medium. By the internal pressure inside the cavity and the evaporation temperature of the selected working medium it can be adjusted at which temperature the air heat exchanger can be operated and/or reaches its highest heat dissipation capacity.

In particular, it may be provided that a porous structure, which has a capillary effect, is arranged in the cavity. The porous structure may, for example, be formed from a sintered material. In an alternative variant, it is also conceivable that the porous structure is formed in the form of a wick, for example made of a steel braiding, which has a capillary effect.

Within the meaning of the present document, a region enclosed by the heat exchanger plate and/or by the carrier plate is understood as evaporator and/or condenser. Thus, the evaporator and/or the condenser are not separate components but may be formed by separate components.

For the purpose of better understanding of the invention, it will be elucidated in more detail by means of the figures below.

These show in a respectively very simplified schematic representation:

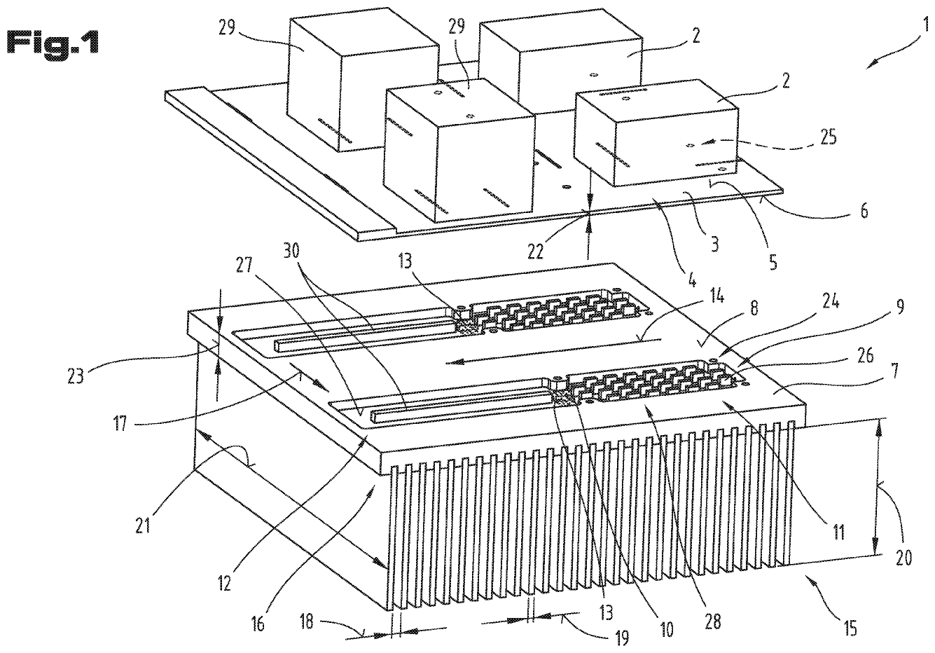

FIG. 1 a perspective view of a first exemplary embodiment of an air heat exchanger;

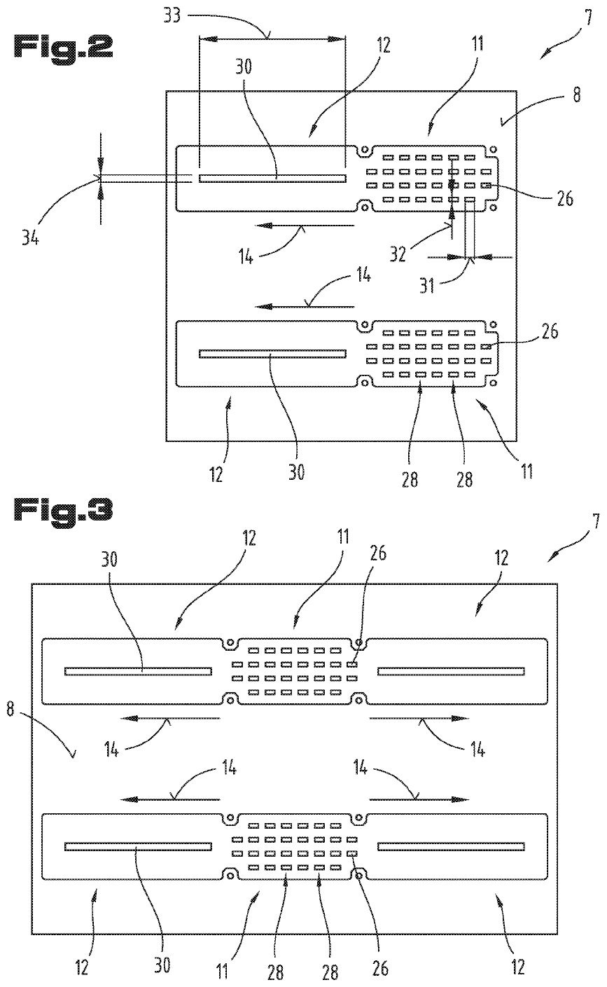

FIG. 2 a top view onto a heat exchanger plate connecting surface of the first exemplary embodiment of the air heat exchanger;

FIG. 3 a top view onto the heat exchanger plate connecting surface of a second exemplary embodiment of the air heat exchanger;

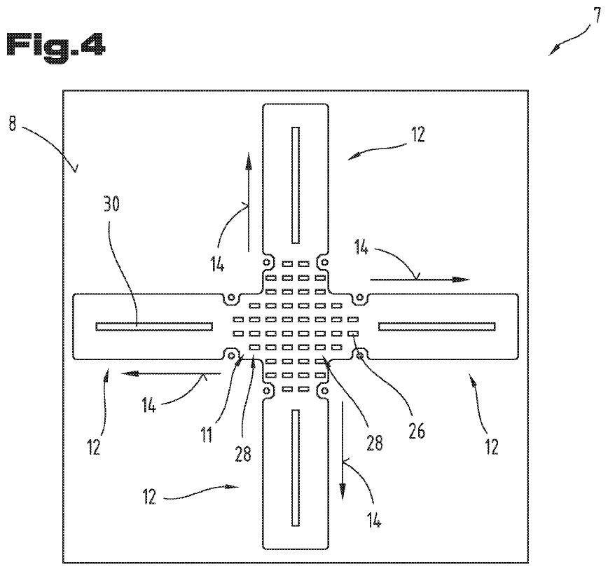

FIG. 4 a top view onto the heat exchanger plate connecting surface of a third exemplary embodiment of the air heat exchanger;

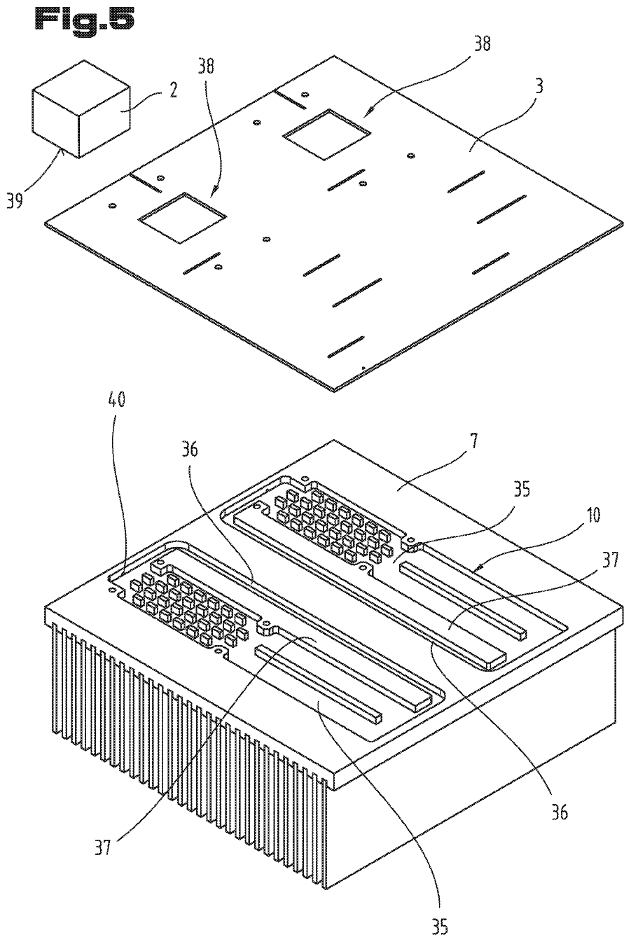

FIG. 5 a perspective view of a further exemplary embodiment of the air heat exchanger with a vapor flow channel and a liquid return channel;

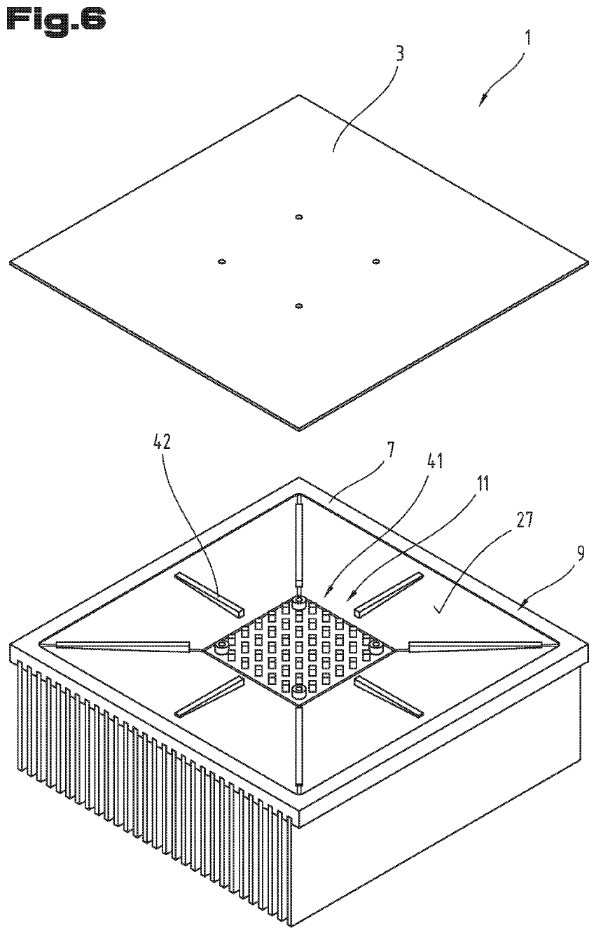

FIG. 6 a perspective view of a further exemplary embodiment of the air heat exchanger with a depression;

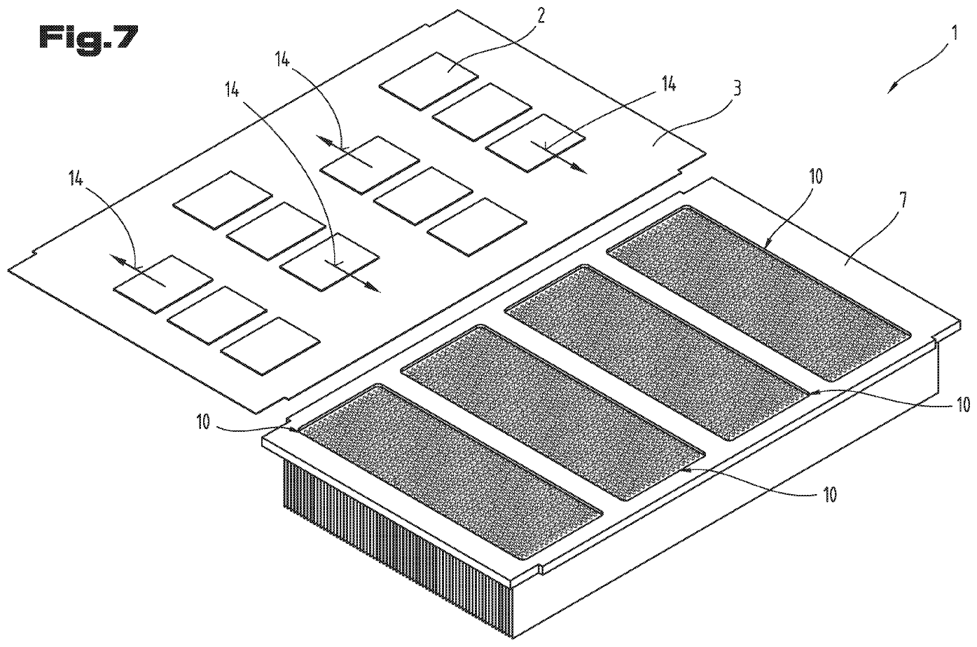

FIG. 7 a perspective view of a further exemplary embodiment of the air heat exchanger with a vapor flow channel and a liquid return channel;

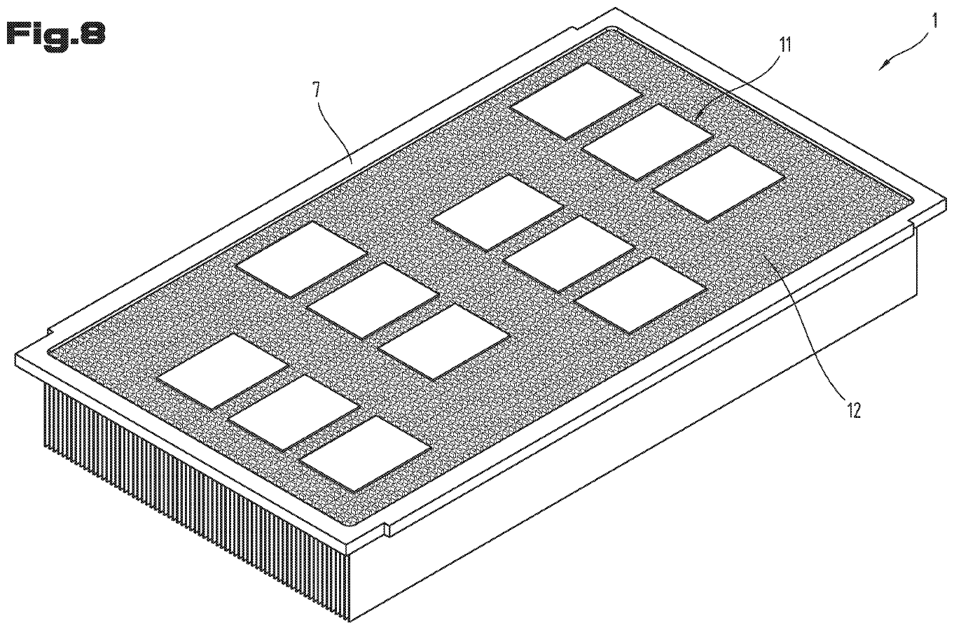

FIG. 8 a perspective view of a further exemplary embodiment of the air heat exchanger with a cavity and multiple evaporators formed on the cavity;

FIG. 9 a top view onto the heat exchanger plate connecting surface of a further exemplary embodiment of the air heat exchanger with a vapor flow channel and a liquid return channel.

First of all, it is to be noted that in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure and in case of a change of position, these specifications of location are to be analogously transferred to the new position.

FIG. 1 shows a perspective view of a first exemplary embodiment of an air heat exchanger 1 for cooling a power electronics component 2. A power electronics component 2 to be cooled in such way may, for example, be an insulated-gate bipolar transistor. The air heat exchanger 1 comprises a carrier plate 3 with an accommodating region 4 for accommodating the power electronics component 2. The accommodating region 4 is formed on an accommodating side 5 of the carrier plate 3. A carrier plate connecting surface 6 is formed on the side of the carrier plate 3 opposite to the accommodating side 5.

Furthermore, the air heat exchanger 1 comprises a heat exchanger plate 7. The heat exchanger plate 7 comprises a heat exchanger plate connecting surface 8 which abuts on the carrier plate connecting surface 6 in the assembled state of the air heat exchanger 1.

FIG. 1 shows the air heat exchanger 1 in an exploded view for the sake of better overview, wherein the carrier plate 3 is represented being elevated from the heat exchanger plate 7. In the installed state of the air heat exchanger 1, the carrier plate connecting surfaces 6 and the heat exchanger plate connecting surfaces 8 are coupled to one another by a materially bonded connection.

As can be seen from FIG. 1, it may be provided that a recess 9, which in the assembled state of the carrier plate 3 and the heat exchanger plate 7 forms a hermetically sealed cavity 10, is formed in the heat exchanger plate 7, in particular in the heat exchanger plate connecting surface 8.

An evaporator 11 and a condenser 12 are formed in the cavity 10, wherein a working medium 13 received in the cavity 10 vaporizes upon heat input in the region of the evaporator 11 and subsequently arrives at the condenser 12, where it condenses again. In this regard, the specific enthalpy of evaporation of the working medium is used to conduct the heat energy from the evaporator 11 to the condenser 12 and hence achieve a uniform heat distribution within the heat exchanger plate 7. Since the working medium 13 transports the heat energy from the evaporator 11 to the condenser 12, the path from the evaporator 11 to the condenser 12 may also be considered the heat transport direction 14.

The working medium 13 condensed in the condenser 12 may arrive back in the evaporator 11 either by the wick effect of a porous structure or by gravity.

Cooling ribs 15 are arranged on the side opposite to the heat exchanger plate connecting surface 8. In particular, it may be provided that a cooling rib receptacle 16 is formed into which cooling ribs 15 are inserted and which serves for transmission of the heat energy from the heat exchanger plate 7 onto the cooling ribs 15.

In an alternative embodiment variant, which is not shown, it may be provided that the cooling ribs 15 are formed in one piece with the heat exchanger plate 7.

As can further be seen from FIG. 1, it may be provided that the cooling ribs 15 extends in a transverse direction 17. In this regard, the transverse direction 17 may be arranged at a right angle to the heat transport direction 14 as seen in a top view onto the heat exchanger plate connecting surface 8.

The individual cooling ribs 15 are arranged at a cooling rib distance 18 to one another and have a cooling rib thickness 19. In particular, it may be provided that the cooling rib thickness 19 amounts to between 20% and 350%, in particular between 80% and 200%, preferably between 140% and 160%, of the cooling rib distance 18. Furthermore, it may be provided that the cooling ribs 15 are formed so as to project as compared to the cooling rib receptacle 16 by a cooling rib projection 20. The cooling rib projection 20 may amount to 20 to 25 times the cooling rib thickness 19. In particular, it may be provided that the cooling rib projection 20 amounts to between 50 mm and 150 mm, in particular between 70 mm and 120 mm, preferably between 90 mm and 95 mm.

Furthermore, it may be provided that the cooling rib distance 18 amounts to between 1 mm and 20 mm, in particular between 3 mm and 15 mm, preferably between 5 mm and 7 mm.

Furthermore, it may be provided that the cooling rib thickness 19 amounts to between 1 mm and 20 mm, in particular between 2 mm and 10 mm, preferably between 3 mm and 5 mm.

Furthermore, it may be provided that the cooling ribs 15 in their longitudinal extension have a cooling rib depth 21, which extends in transverse direction 17. The cooling rib depth 21 may amount to between 100 mm and 500 mm, in particular between 300 mm and 400 mm, preferably between 250 mm and 350 mm.

The carrier plate 3 may have a carrier plate thickness 22. The heat exchanger plate 7 has a heat exchanger plate thickness 23.

Furthermore, it may be provided that in the heat exchanger plate 7, in particular in the region of the evaporator 11, thread elements 24 are formed which serve for receiving fastening screws for the power electronics components 2. The thread elements 24 may correspond to corresponding through holes 25 in the carrier plate 3. By such a combination of thread elements 24 and through holes 25, it may be achieved that the heat exchanger plate thickness 23 which is larger in comparison to the carrier plate thickness 22 may be used for securely and durably receiving a fastening screw.

The recess 9 of the heat exchanger plate 7 extends starting from the heat exchanger plate connecting surface 8 to a recess base 27.

As can further be seen from FIG. 1, it may be provided that one or multiple webs 26, which extend between the recess base 27 of the recess 9 and the heat exchanger plate connecting surface 8, are arranged in the region of the evaporator 11. The webs 26 serve for better heat transfer from the carrier plate 3 to the evaporator 11. In particular, it is provided that in the assembled state of the air heat exchanger 1, the webs 26 abut on the carrier plate connecting surface 6 of the carrier plate 3.

As can further be seen from FIG. 1, it may be provided that the webs 26 are in each case arranged in a row 28, wherein multiple rows 28 of webs 26 can be arranged behind one another as seen in the heat transport direction 14.

Furthermore, it may be provided that further electronic components 29 are arranged on the carrier plate 3 in the region of the condenser 12.

As can further be seen from FIG. 1, it may be provided that a spacer 30 is formed in the region of the condenser. The spacer 30 can serve for supporting the carrier plate 3 in the region of the condenser 12.

FIG. 2 shows the heat exchanger plate 7 in a top view onto the heat exchanger plate connecting surface 8, wherein again, equal reference numbers and/or component designations are used for equal parts as before in FIG. 1. In order to avoid unnecessary repetitions, it is pointed to/reference is made to the detailed description in FIG. 1 preceding it.

As can be seen from FIG. 2, the webs 26 each have a longitudinal extension 31 and a transverse extension 32. The spacer 30 also has a longitudinal extension 33 and a transverse extension 34.

In FIG. 3, a further and possibly independent embodiment of the air heat exchanger 1 is shown, wherein again equal reference numbers and/or component designations are used for equal parts as in the preceding FIGS. 1 and 2. In order to avoid unnecessary repetitions, it is pointed to/reference is made to the detailed description in FIGS. 1 and 2 preceding it.

FIG. 3 shows the air heat exchanger 1 in a view as was selected in FIG. 2. As can be seen from FIG. 3, it may be provided that the evaporator 11 is formed centrally on the heat exchanger plate 7 and that a condenser 12 is formed on both sides of the evaporator 11. Thus, in the operation of the air heat exchanger 1, starting out from the evaporator 11, a first heat transport direction 14 and a second heat transport direction 14 are established, which each lead from the evaporator 11 to the condenser 12. By this measure, the possible heat dissipation may be improved since the heat dissipation may be carried out in different directions.

In FIG. 4, a further and possibly independent embodiment of the air heat exchanger 1 is shown, wherein again equal reference numbers and/or component designations are used for equal parts as in the preceding FIGS. 1 to 3. In order to avoid unnecessary repetitions, it is pointed to/reference is made to the detailed description in FIGS. 1 through 3 preceding it.

As can be seen from FIG. 4, it may be provided that not only two condensers 12 being opposite to one another are formed but that multiple condensers 12, in particular four condensers 12, which may, for example, be formed in star shape, adjoin the evaporator 11. In this regard, the evaporator 11 may, for example, be arranged in the center of the heat exchanger plate 7.

Of course, in a further embodiment variant, three or more than four condensers 12 may also be arranged around the evaporator 11 in star shape.

FIGS. 5 to 9 each show a further exemplary embodiment of the air heat exchanger 1, wherein again, equal reference numbers and/or component designations are used for equal parts as in the respective preceding figures. In order to avoid unnecessary repetitions, it is pointed to/reference is made to the detailed description in FIG. 1 preceding it. As can be seen in FIG. 5, it may be provided that the cavity 10 comprises a vapor flow channel 35 and comprises a liquid return channel 36 constructionally separated therefrom. A separating web 37 may be arranged between the vapor flow channel 35 and the liquid return channel 36.

It can further be seen from FIG. 5 that it may be provided that an opening 38, which is arranged in the region in which the power electronics component 2 is installed, is formed in the carrier plate 3. Thus, a footing 39 of the power electronics component 2 may close the opening 38 in the installed state and thus be placed on the opening 38 or inserted into the opening 38. Thereby, the footing 39 of the power electronics component 2 may at the same time represent a limitation for the cavity 10. By this measure, the heat energy may be transferred as efficiently as possible from the power electronics component 2 to the working medium 13 accommodated in the cavity 10.

As can further be seen from FIG. 5, it may be provided that a filling opening 40, which serves for filling the cavity 10 with the working medium 13, is formed. The filling opening 40 may, for example, be arranged in a side surface of the cavity 10. Furthermore, it may be provided that the filling opening 40 is formed in the heat exchanger plate 7.

When the power electronics component 2 serves for closing the cavity 10, it may also be provided that the webs 26 are arranged directly on the footing 39 of the power electronics component 2.

As can be seen from FIG. 6, it may be provided that a depression 41, which is arranged in the region of the condenser 12, is formed in the recess base 27 of the recess 9. In the provided installation position of the air heat exchanger 1, the depression 41 has its deepest point the region of the evaporator 11.

As may further be seen from FIG. 6, it may be provided that the depression 41 and thus the evaporator 11 is arranged in the center of the heat exchanger plate 7. The condenser 12 is thus formed so as to surround the evaporator 11. Furthermore, support webs 42 are provided which serve for supporting the carrier plate on the heat exchanger plate 7.

As can be seen from FIG. 7, it may be provided that multiple cavities 10, which have a different and/or opposing heat transport direction 14, are formed next to one another. By this measure, a homogeneous temperature distribution may be achieved as seen across the entire heat exchanger plate 7.

In the exemplary embodiment according to FIG. 7, the power electronics components 2 are schematically indicated in the form of rectangles on the carrier plate 3.

FIG. 8 schematically indicated the power electronics components 2, the carrier plate 3 not being shown for the sake of better overview. As can be seen from FIG. 8, it may be provided that merely one single large cavity 10 is formed which comprises multiple evaporators 11 and multiple condensers 12. In this regard, the evaporators 11 are each formed in the region of the power electronics component 2 and the condensers 12 are formed on the remaining surface.

The exemplary embodiment according to FIG. 9 generally has the same structure as the exemplary embodiment according to FIG. 5. As can be seen from FIG. 9, it may be provided that the air heat exchanger 1 has a standing arrangement, such that the evaporator 11 is formed below the condenser 12 in the operational state of the air heat exchanger 1, which allows the working medium 13 to pass from the condenser 12 into the evaporator 11 by the action of gravity. In the exemplary embodiment according to FIG. 9, a cavity side surface 43 of the cavity 10 has an incline from the vapor flow channel 35 to the liquid return channel 36, which allows the working medium 13 condensed on the cavity side surface 43 to pass into the liquid return channel 36 by gravity.

The exemplary embodiments show possible embodiment variants, and it should be noted in this respect that the invention is not restricted to these particular illustrated embodiment variants of it, but that rather also various combinations of the individual embodiment variants are possible and that this possibility of variation owing to the technical teaching provided by the present invention lies within the ability of the person skilled in the art in this technical field.

The scope of protection is determined by the claims. Nevertheless, the description and drawings are to be used for construing the claims. Individual features or feature combinations from the different exemplary embodiments shown and described may represent independent inventive solutions. The object underlying the independent inventive solutions may be gathered from the description.

All indications regarding ranges of values in the present description are to be understood such that these also comprise random and all partial ranges from it, for example, the indication 1 to 10 is to be understood such that it comprises all partial ranges based on the lower limit 1 and the upper limit 10, i.e. all partial ranges start with a lower limit of 1 or larger and end with an upper limit of 10 or less, for example 1 through 1.7, or 3.2 through 8.1, or 5.5 through 10.

Finally, as a matter of form, it should be noted that for ease of understanding of the structure, elements are partially not depicted to scale and/or are enlarged and/or are reduced in size.

### LIST OF REFERENCE NUMBERS

1 Air heat exchanger
2 Power electronics component
3 Carrier plate
4 Accommodating region
5 Accommodating side
6 Carrier plate connecting surface
7 Heat exchanger plate
8 Heat exchanger plate connecting surface
9 Recess
10 Cavity
11 Evaporator
12 Condenser
13 Working medium
14 Heat transport direction
15 Cooling rib
16 Cooling rib receptacle
17 Transverse direction
18 Cooling rib distance
19 Cooling rib thickness
20 Cooling rib projection
21 Cooling rib depth
22 Carrier plate thickness
23 Heat exchanger plate thickness
24 Thread element
25 Through hole
26 Web
27 Recess base
28 Row
29 Further electronic component
30 Spacer
31 Longitudinal extension of web
32 Transverse extension of web
33 Longitudinal extension of spacer
34 Transverse extension of spacer
35 Vapor flow channel
36 Liquid return channel
37 Separating web
38 Opening
39 Footing
40 Filling opening
41 Depression
42 Support web
43 Cavity side surface

1.-28. (canceled)

29. An air heat exchanger (1) for cooling a power electronics component (2), comprising:
a carrier plate (3) having an accommodating region (4) for accommodating the power electronics component (2);
a heat exchanger plate (7) which is coupled to the carrier plate (3), wherein at least one hermetically sealed cavity (10) for accommodating a working medium (13) is formed and at least partly delimited by the carrier plate (3) and the heat exchanger plate (7), wherein the cavity (10) comprises an evaporator (11) and a condenser (12), wherein the evaporator (11) is arranged so as to be spaced apart from the condenser (12) in a heat transport direction (14);
cooling ribs (15) which are coupled to the heat exchanger plate (7), wherein the carrier plate (3) has a carrier plate connecting surface (6) and the heat exchanger plate (7) has a heat exchanger plate connecting surface (8), wherein the carrier plate connecting surface (6) and the heat exchanger plate connecting surface (8) abut on one another, and wherein the carrier plate connecting surface (6) and the heat exchanger plate connecting surface (8) are coupled to one another by vacuum brazing connection.

30. The air heat exchanger (1) according to claim 29, wherein the carrier plate connecting surface (6) and the heat exchanger plate connecting surface (8) are each formed as planar surfaces, wherein the cavity (10) is formed by a recess (9) in the heat exchanger plate connecting surface (8).

31. The air heat exchanger (1) according to claim 30, wherein webs (26) are arranged in the recess (9) at least in the region of the evaporator (11), said webs (26) abutting on the carrier plate connecting surface (6).

32. The air heat exchanger (1) according to claim 31, wherein multiple ones of the webs (26) are arranged in a row (28), wherein multiple rows (28) of webs (26) are arranged behind one another.

33. The air heat exchanger (1) according to claim 32, wherein the individual webs (26) of one row (28) and/or of different rows (28) have a dimensioning differing from one another and/or wherein the individual webs (26) are arranged at different distances from one another.

34. The air heat exchanger (1) according to claim 29, wherein at least two cavities (10) are formed.

35. The air heat exchanger (1) according to claim 29, wherein cooling rib receptacles (16), in which the cooling ribs (15) are received, are formed in the heat exchanger plate (7).

36. The air heat exchanger (1) according to claim 29, wherein cooling ribs (15) are formed in one piece with the heat exchanger plate (7).

37. The air heat exchanger (1) according to claim 29, wherein the evaporator (11) is arranged in the accommodating region (4), wherein the accommodating region (4) is arranged off-center of the carrier plate (3) as seen in top view.

38. The air heat exchanger (1) according to claim 29, wherein the cavity (10) comprises the evaporator (11) and multiple ones of the condensers (12), wherein multiple heat transport directions (14) are formed.

29. The air heat exchanger (1) according to claim 29, wherein the carrier plate (3) has a carrier plate thickness (22) of between 1 mm and 10 mm, in particular between 1.3 mm and 7.5 mm, preferably between 1.5 mm and 5 mm.

40. The air heat exchanger (1) according to claim 29, wherein the heat exchanger plate (7) has a heat exchanger plate thickness (23) of between 3 mm and 50 mm, in particular between 4 mm and 35 mm, preferably between 5 mm and 23 mm.

41. The air heat exchanger (1) according to claim 29, wherein a carrier plate thickness (22) amounts to between 2% and 300%, in particular between 5% and 70%, preferably between 15% and 30% of a heat exchanger plate thickness (23).

42. The air heat exchanger (1) according to claim 29, wherein the cooling ribs (15) are arranged such that the longitudinal extension of the cooling ribs (15) as seen in top view onto the heat exchanger plate connecting surface (8) are formed transversely to the heat transport direction (14).

43. The air heat exchanger (1) according to claim 29, wherein an opening (38) is formed in the carrier plate (3), said opening being designed to be closed by means of a footing (39) of the power electronics component (2).

44. The air heat exchanger (1) according to claim 29, wherein the cavity (10) comprises a vapor flow channel (35) and a liquid return channel (36) at a constructional distance therefrom.

45. The air heat exchanger (1) according to claim 44, wherein a porous structure or a wick is arranged in the liquid return channel (36).

46. The air heat exchanger (1) according to claim 29, wherein a depression (41), which has its deepest point in the region of the evaporator (11), is formed in a recess base (27) of the recess (9).

47. The air heat exchanger (1) according to claim 29, wherein multiple evaporators (11) and/or multiple condensers (12) are formed in a cavity (10).

48. The air heat exchanger (1) according to claim 34, wherein the at least two cavities (10) are arranged next to one another, wherein the at least two cavities (10) have opposite heat transport directions (14).

49. The air heat exchanger (1) according to claim 29, wherein a filling opening (40) that is in flow connection with the cavity (10) is formed in the carrier plate (3) or in the heat exchanger plate (7).

50. The air heat exchanger (1) according to claim 49, wherein the filling opening (40) in the installed state of the air heat exchanger (1) is pressed in such a way that it is tightly sealed.

51. An electronic assembly comprising:
an air heat exchanger (1);
a power electronics component (2), in particular an insulated-gate bipolar transistor, arranged on the air heat exchanger (1);
wherein
the air heat exchanger (1) is formed according to claim 29.

52. The electronic assembly according to claim 51, wherein the power electronics component (2) is arranged in the region of the evaporator (11) of the air heat exchanger (1) and wherein a further electronic component (29) is arranged in the region of the condenser (12), wherein the further electronic component (29) has a lower heat dissipation performance than a heat dissipation performance of the power electronics component (2).

53. The electronic assembly according to claim 51, wherein an opening (38) is formed in the carrier plate (3), wherein the power electronics component (2) is mounted on the carrier plate (3) such that a footing (39) of the power electronics component (2) closes the recess and delimits the cavity (10).

54. A method for producing the air heat exchanger (1) according to claim 29, comprising the method steps:
connecting a carrier plate (3) to a heat exchanger plate (7), wherein the carrier plate (3) has a carrier plate connecting surface (6) and the heat exchanger plate (7) has a heat exchanger plate connecting surface (8), wherein the carrier plate connecting surface (6) and the heat exchanger plate connecting surface (8) abut on one another, wherein the carrier plate connecting surface (6) and the heat exchanger plate connecting surface (8) are coupled to one another by a vacuum brazing connection;
filling a cavity (10) with a working medium (13) via the filling opening (40);
setting the desired pressure in the cavity (10); and
hermetically sealing the cavity (10) by pressing the filling opening (40).
